(19) United States
(12) Patent Application Publication
(10) Pub. No.: US 2025/0149317 A1
(43) Pub. Date: May 8, 2025

(54) SEMICONDUCTOR MANUFACTURING APPARATUS AND METHOD OF CONTROLLING PHYSICAL QUANTITY OF SEMICONDUCTOR MANUFACTURING APPARATUS

(71) Applicant: Samsung Electronics Co., Ltd., Suwon-si (KR)

(72) Inventors: Yunha Kim, Suwon-si (KR); Kwanghyun Cho, Suwon-si (KR); Jonghwa Kim, Suwon-si (KR); Sanghoon Kim, Suwon-si (KR); Hansung Cho, Suwon-si (KR)

(21) Appl. No.: 18/658,293

(22) Filed: May 8, 2024

(30) Foreign Application Priority Data
Nov. 7, 2023 (KR) 10-2023-0153106

(51) Int. Cl. H01J 37/32

(52) U.S. Cl. CPC H01J 37/3299; H01J 37/32174; H01J 37/32449; H01J 37/32522; H01J 37/32816; H01J 2237/334

(57) ABSTRACT

A method of controlling a physical quantity of a semiconductor manufacturing facility includes performing feedforward control including control of a first stage feedforward to accelerate a physical quantity control system to a physical limit performance and control of a second stage feedforward to reduce acceleration of the physical quantity control system at a first switching point, switching the feedforward control to feedback control at a second switching point, and performing feedback control on the physical quantity control system.

### CROSS-REFERENCE TO RELATED APPLICATION

This application is based on and claims priority under 35 U.S.C. § 119 to Korean Patent Application No. 10-2023-0153106, filed on Nov. 7, 2023 in the Korean Intellectual Property Office, the disclosure of which is incorporated by reference herein in its entirety.

### BACKGROUND

The inventive concept relates to a semiconductor manufacturing apparatus and a method of controlling a physical quantity of the semiconductor manufacturing apparatus, and more particularly, to a semiconductor manufacturing apparatus capable of securing fast response characteristics of physical quantity control, and a method of controlling a physical quantity of the semiconductor manufacturing apparatus.

Generally, semiconductor devices are manufactured by performing a deposition process, a photolithography process, an etching process, etc., and forming fine circuit patterns on an upper surface of a substrate.

The control performance of such semiconductor manufacturing facilities is directly related to the homeostasis of a semiconductor manufacturing process, and the importance thereof is emphasized. It is well known that facility physical quantities such as temperature, pressure, flow rate, and radio frequency (RF) power where a process takes place affect manufacturing quality and yield, and efforts to improve the control homeostasis of semiconductor facilities by securing the fast response performance of such physical quantities are continuing.

### SUMMARY

The inventive concept provides a semiconductor manufacturing apparatus capable of securing the fast response performance of a facility physical quantity by applying feedforward control technology, and a method of controlling a physical quantity of the semiconductor manufacturing apparatus.

In addition, the problem to be solved by the technical idea of the inventive concept is not limited to the problem mentioned above, and other problems may be clearly understood by one of ordinary skill in the art from the description below.

The inventive concept provides a method of controlling a physical quantity of a semiconductor manufacturing apparatus, a semiconductor manufacturing apparatus, and a semiconductor manufacturing system.

According to an aspect of the inventive concept, there is provided a method of controlling a physical quantity of a semiconductor manufacturing apparatus including performing feedforward control including control of a first stage feedforward to accelerate a physical quantity control system to a physical limit performance and control of a second stage feedforward to reduce acceleration of the physical quantity control system at a first switching point, switching the feedforward control to feedback control at a second switching point, and performing feedback control on the physical quantity control system.

According to another aspect of the inventive concept, there is provided semiconductor manufacturing system including a main system controller; a sub-system controller configured to receive a process recipe from the main system controller, and a semiconductor manufacturing facility controlled by the sub-system controller and where a semiconductor process is performed based on the process recipe received from the main system controller, wherein the sub-system controller includes a process module controller (PMC) and a plurality of sub-controllers, and wherein at least one of the main system controller, the PMC, and the plurality of sub-controllers of the sub-system controller includes a feedforward controller configured to perform feedforward control including control of a first stage feedforward to accelerate a physical quantity control system to a physical limit performance and control of a second stage feedforward to reduce acceleration of the physical quantity control system at a first switching point, a switching unit configured to switch the feedforward control to feedback control at a second switching point, and a feedback controller configured to perform feedback control on the physical quantity control system.

According to another aspect of the inventive concept, there is provided a semiconductor manufacturing system including a semiconductor manufacturing facility including a process chamber, at least one electrode configured to apply power or an electromagnetic physical quantity to the process chamber, a heater configured to apply heat to the inside of the process chamber, a flow valve configured to control a flow rate of fluid flowing into the process chamber, a pressure valve to control pressure of the inside of the process chamber, a stage configured to drive a support, and at least one sensor configured to measure a physical quantity to be controlled in the process chamber, and a system controller including a process module controller (PMC) and a plurality of sub-controllers and configured to control the semiconductor manufacturing facility where a semiconductor manufacturing process is performed, wherein at least one of the PMC and the plurality of sub-controllers includes a feedforward controller configured to feedforward control a physical quantity control system to output a first stage feedforward to accelerate the physical quantity control system to a physical limit performance and to output a second stage feedforward to reduce acceleration of the physical quantity control system at a first switching point, a feedback controller configured to feedback control the physical quantity control system, and a switching unit configured to switch from feedforward control to feedback control at a second switching point.

According to another aspect of the inventive concept, there is provided a semiconductor manufacturing system including a main system controller, a sub-system controller configured to receive a process recipe from the main system controller, and a semiconductor manufacturing facility controlled by the sub-system controller and where a semiconductor process is performed based on the process recipe received from the main system controller, wherein the semiconductor manufacturing facility includes a process chamber, at least one electrode configured to apply radio frequency (RF) power or an electromagnetic physical quantity to generate plasma within the process chamber, a heater configured to apply heat to an inside of the process chamber, a flow valve configured to control a flow rate of fluid flowing into the process chamber, a pressure valve configured to control pressure of the inside of the process chamber, a stage configured to drive a support, and at least one sensor configured to measure a physical quantity to be controlled in the process chamber, the sub-system controller includes a PMC and a plurality of sub-controllers, at least one of the main system controller, the PMC and the plurality of sub-controllers of the sub-system controller includes a feedforward controller configured to feedforward control a physical quantity control system to output a first stage feedforward to accelerate the physical quantity control system to a physical limit performance and output a second stage feedforward to reduce acceleration of the physical quantity control system at a first switching point, a feedback controller configured to feedback control the physical quantity control system, and a switching unit configured to switch from feedforward control to feedback control at a second switching point.

### BRIEF DESCRIPTION OF THE DRAWINGS

Example embodiments will be more clearly understood from the following detailed description taken in conjunction with the accompanying drawings in which:

FIG. 1 is a schematic diagram schematically showing a semiconductor manufacturing system according to some embodiments;

FIG. 2 schematically shows a block diagram of a physical quantity control system including a physical quantity controller with a feedforward control function according to some embodiments;

FIG. 3A shows an example of the physical quantity controller of FIG. 2 applied to a main system controller, FIG. 3B shows an example of the physical quantity controller of FIG. 2 applied to a process module controller (PMC), and FIG. 3C shows an example of the physical quantity controller of FIG. 2 applied to a sub-controller;

FIGS. 4A and 4B show comparison of the physical quantity control system according to an embodiment and a physical quantity control system of the comparative example and response performance thereof;

FIG. 5 is a graph showing response characteristics of a chamber pressure control system of a semiconductor etching process facility according to an embodiment;

FIG. 6 is a graph showing response characteristics at a switching point between a second stage feedforward control and a feedback control;

FIG. 7 is a graph showing that it is possible to secure optimal pressure control performance of the desired standard through iteration implementation of adjusting a feedforward application amount based on a system response;

FIG. 8 is a flowchart schematically showing a method of controlling a physical quantity of a semiconductor manufacturing apparatus according to some embodiments;

FIG. 9 is a flowchart schematically showing a method of controlling a physical quantity of a semiconductor manufacturing apparatus according to some other embodiments;

FIG. 10A is a graph showing an example of securing robust and fast pressure control performance by applying a physical quantity controller according to some embodiments to a semiconductor etching process facility; and

FIG. 10B is an enlarged graph showing an iteration period of FIG. 10A.

### DETAILED DESCRIPTION

Hereinafter, example embodiments of the inventive concept will be described in detail with reference to the attached drawings. The same reference numerals are used for the same components in the drawings, and redundant descriptions thereof may be omitted in the interest of brevity.

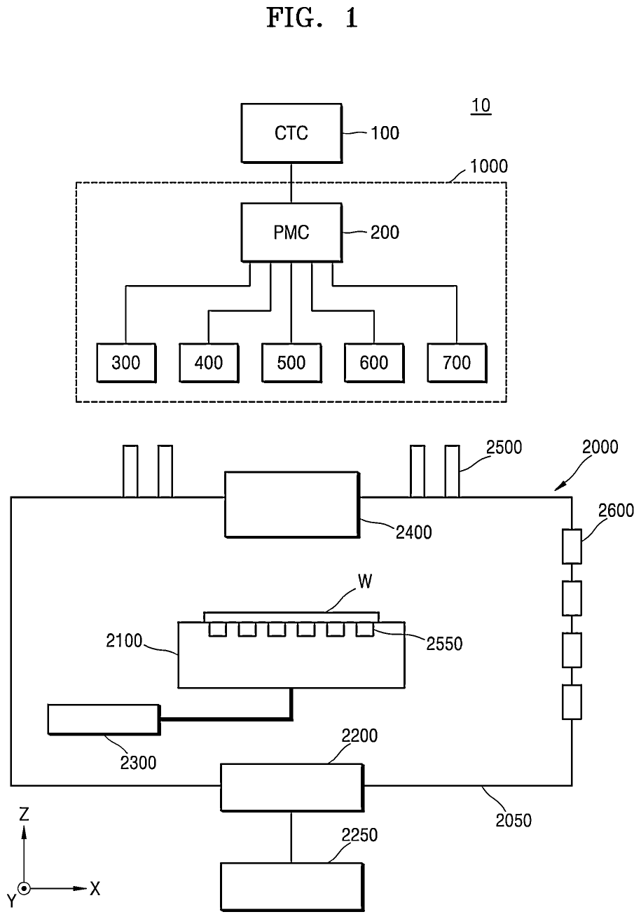

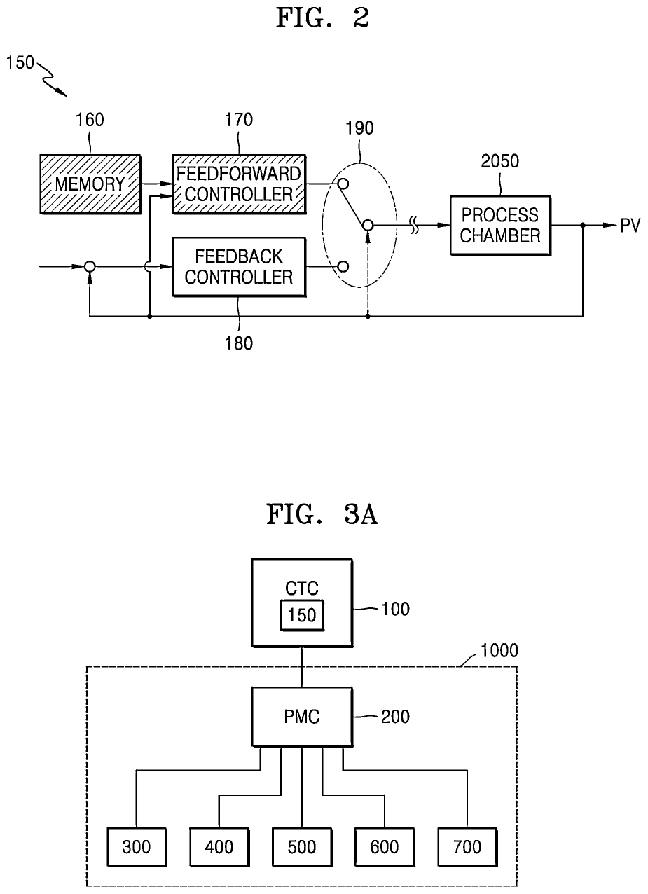

FIG. 1 is a schematic diagram schematically showing a semiconductor manufacturing system 10 according to some embodiments. FIG. 2 schematically shows a block diagram of a physical quantity control system including a physical quantity controller 150 having a feedforward control function according to some embodiments.

Referring to FIGS. 1 and 2, the semiconductor manufacturing system 10 may include a main system controller 100 and at least one semiconductor manufacturing apparatus, and the semiconductor manufacturing apparatus may include at least one sub-system controller 1000 and at least one semiconductor manufacturing facility or equipment 2000. That is, the semiconductor manufacturing system 10 may include the main system controller 100, the at least one sub-system controller 1000, and the at least one semiconductor manufacturing facility 2000.

The main system controller 100 may be configured to control the sub-system controller 1000 of the semiconductor manufacturing apparatus and the semiconductor manufacturing facility 2000. According to an embodiment, the main system controller 100 may include a cluster tool controller (CTC). The main system controller 100 may be configured to set a process recipe for performing a manufacturing process performed by the semiconductor manufacturing facility 2000, scheduling of steps included in the process recipe, etc. The main system controller 100 may be configured to transmit the process recipe to the sub-system controller 1000. According to some embodiments, the main system controller 100 may be connected to one or more sub-system controllers 1000 and may interact with the one or more sub-system controllers 1000. For example, the semiconductor manufacturing system 10 may include a plurality of sub-system controllers 1000 controlled by one main system controller 100, and a plurality of semiconductor manufacturing facilities 2000 respectively controlled by the plurality of sub-system controllers 1000.

The sub-system controller 1000 may control the semiconductor manufacturing facility 2000 based on the process recipe received from the main system controller 100. The sub-system controller 1000 includes a process module controller (PMC) 200, a first sub-controller 300, a second sub-controller 400, a third sub-controller 500, a fourth sub-controller 600, and a fifth sub-controller 700.

The PMC 200 may provide information about a process of processing a substrate W performed by the semiconductor manufacturing facility 2000 to each of the first sub-controller 300, the second sub-controller 400, the third sub-controller 500, the fourth sub-controller 600, and the fifth sub-controller 700. Specifically, the PMC 200 may transmit an input signal to each of the first sub-controller 300, the second sub-controller 400, the third sub-controller 500, the fourth sub-controller 600, and the fifth sub-controller 700. Here, the number of sub-controllers included in the sub-system controller 1000 and to which information is transmitted from the PMC 200 is not limited to 5, and may be 2 or more, 5 or less, or more than 5. Here, an example in which the sub-system controller 1000 includes five sub-controllers is shown and described, but the inventive concept is not limited thereto.

Each of the first sub-controller 300, the second sub-controller 400, the third sub-controller 500, the fourth sub-controller 600, and the fifth sub-controller 700 may be configured to control a physical quantity of the semiconductor manufacturing facility 2000. According to an embodiment, the physical quantity may include pressure inside the semiconductor manufacturing facility 2000, a flow rate of fluid flowing into the semiconductor manufacturing facility 2000, source and bias radio frequency (RF) power applied to inside the semiconductor manufacturing facility 2000, the driving amount of a support 2100, a process temperature inside the semiconductor manufacturing facility 2000, electromagnetic physical quantities such as voltage, current, magnetic flux applied to the semiconductor manufacturing facility 2000, and mechanical physical quantities such as the position, speed, acceleration, and force applied to the semiconductor manufacturing facility 2000. The mechanical physical quantity applied to the semiconductor manufacturing facility 2000 may be a physical quantity related to the driving of the support 2100, or may be a physical quantity related to a stage 2300 for driving the support 2100 and the substrate W supported by the support 2100. Accordingly, the first sub-controller 300, the second sub-controller 400, the third sub-controller 500, the fourth sub-controller 600, and the fifth sub-controller 700 may each control different physical quantities among the physical quantities. To this end, the first sub-controller 300, the second sub-controller 400, the third sub-controller 500, the fourth sub-controller 600, and the fifth sub-controller 700 may each be configured to control any one of the components included in the semiconductor manufacturing facility 2000.

For example, when the first sub-controller 300 controls the flow rate of fluid flowing into the semiconductor manufacturing facility 2000, the second sub-controller 400 may be configured to control the pressure inside the semiconductor manufacturing facility 2000, the third sub-controller 500 may be configured to control the process temperature inside the semiconductor manufacturing facility 2000, the fourth sub-controller 600 may be configured to control the source and bias RF power applied to inside the semiconductor manufacturing facility 2000, and the fifth sub-controller 700 may be configured to control the driving amount of the support 2100. At this time, the first sub-controller 300, the second sub-controller 400, the third sub-controller 500, the fourth sub-controller 600, and the fifth sub-controller 700 may each be connected to a component. For example, the first sub-controller 300 may be connected to a flow valve 2400 that controls the flow rate of fluid flowing into an upper portion of a chamber 2050, the second sub-controller 400 may be connected to a pressure valve 2200 that controls pressure inside the chamber 2050, the third sub-controller 500 may be connected to a heater 2600 that adjusts the temperature inside the chamber 2050, and the fourth sub-controller 600 may be connected to, for example, an upper electrode 2500 and a lower electrode 2550 to generate plasma inside the chamber 2050. The fourth sub-controller 600 may include two sub-controllers respectively connected to the upper electrode 2500 and the lower electrode 2550. The fifth sub-controller 700 may be connected to the stage 2300 that drives the support 2100. However, the inventive concept is not limited thereto.

For example, at least any two of the first sub-controller 300, the second sub-controller 400, the third sub-controller 500, the fourth sub-controller 600, and the fifth sub-controller 700 may also control the same physical quantity. Additionally, a sub-controller may be additionally provided. For example, the first sub-controller 300 and the second sub-controller 400 may control the flow rate of fluid flowing into the semiconductor manufacturing facility 2000, and the remaining sub-controllers may respectively control the pressure inside the semiconductor manufacturing facility 2000, the temperature inside the semiconductor manufacturing facility 2000, the source and bias RF power applied to inside the semiconductor manufacturing facility 2000, and the driving amount of the support 2100. However, the first sub-controller 300 and the second sub-controller 400 may be connected to components. For example, the first sub-controller 300 may be connected to the flow valve 2400 that controls the flow rate of fluid flowing into the upper portion of the chamber 2050, and the second sub-controller 400 may be connected to a flow valve (not shown) that adjusts the flow rate of fluid flowing into a lower portion of the chamber 2050.

As described above, the first sub-controller 300, the second sub-controller 400, the third sub-controller 500, the fourth sub-controller 600, and the fifth sub-controller 700 may each be configured to control any one of the components of the semiconductor manufacturing facility 2000. Hereinafter, an example in which the sub-system controller 1000 includes the first sub-controller 300, the second sub-controller 400, the third sub-controller 500, the fourth sub-controller 600, and the fifth sub-controller 700, which are configured to control different components of the semiconductor manufacturing facility 2000 and adjust different physical quantities is described. In addition, hereinafter, an example in which the first sub-controller 300 controls the flow valve 2400, and the second sub-controller 400 controls the pressure valve 2200, etc. is described but the inventive concept is not limited thereto.

The process recipe provided from the main system controller 100 to the sub-system controller 1000 may be provided according to a wired/wireless communication method. For example, communication methods such as Bluetooth (BT), Wireless Fidelity (Wi-Fi), Zigbee, Infrared (IR), Ethernet, Serial Interface, Universal Serial Bus (USB), Ethernet for Control Automation Technology (EtherCAT), Mobile Industry Processor Interface Camera Serial Interface (MIPI CSI), Near Field Communication (NFC), Vehicle to Everything (V2X), cellular communication, etc. may be used. Additionally, the input signal provided from the sub-system controller 1000 to the semiconductor manufacturing facility 2000 may also use the same communication method as described above.

Here, each communication method may be implemented in the form of at least one hardware chip. This hardware chip may be at least one communication chip that performs communication according to various wireless communication standards.

According to some embodiments, based on the process recipe provided to the PMC 200, the PMC 200 may transmit the input signal to each of the first sub-controller 300, the second sub-controller 400, the third sub-controller 500, the fourth sub-controller 600, and the fifth sub-controller 700. At this time, the input signal may be transmitted over an industrial communication network. The input signal transmitted from the PMC 200 may include, for example, a first input signal transmitted to the first sub-controller 300, a second input signal transmitted to the second sub-controller 400, a third input signal transmitted to the third sub-controller 500, a fourth input signal transmitted to the fourth sub-controller 600, and a fifth input signal transmitted to the fifth sub-controller 700.

When the first input signal is transmitted to the first sub-controller 300, a first component connected to the first sub-controller 300 may provide a first output. Likewise, when the second input signal is transmitted to the second sub-controller 400, a second component connected to the second sub-controller 400 may provide a second output, when the third input signal is transmitted to the third sub-controller 500, a third component connected to the third sub-controller 500 may provide a third output, when the fourth input signal is transmitted to the fourth sub-controller 600, a fourth component connected to the fourth sub-controller 600 may provide a fourth output, and when the fifth input signal is transmitted to the fifth sub-controller 700, a fifth component connected to the fifth sub-controller 700 may provide a fifth output.

The first to fifth outputs may be expressed as physical quantities. For example, the first to fifth outputs may be, for example, physical quantities such as flow rate, pressure, temperature, RF power, and driving amount. For example, the first output may be the flow rate of fluid flowing into the chamber 2050 by the flow valve 2400. At this time, the first component connected to the first sub-controller 300 may be understood as the flow valve 2400, and the first sub-controller 300, which has received the first input signal, may control the flow valve 2400 to provide only a first output value, that is, a constant flow rate, into the chamber 2050. In addition, for example, the second output may be the pressure within the chamber 2050. At this time, the second component connected to the second sub-controller 400 may be understood as the pressure valve 2200, and the second sub-controller 400, which has received the second input signal, may control the pressure valve 2200 to provide the pressure within the chamber 2050 as a second output value.

In order to secure fast response performance of these physical quantities and have improved homeostasis of the semiconductor manufacturing process, at least one of the main system controller 100, the PMC 200, and the first to fifth sub-controllers 300, 400, 500, 600, and 700 may be configured to include the physical quantity controller 150 having the feedforward control function as shown in FIG. 2.

Additionally, the sub-system controller 1000 may be provided such that the PMC 200, the first sub-controller 300, the second sub-controller 400, the third sub-controller 500, the fourth sub-controller 600, and the fifth sub-controller 700 are connected to each other over one network and share all signals. For example, the sub-system controller 1000 may predict that at least any two of the first sub-controller 300, the second sub-controller 400, the third sub-controller 500, the fourth sub-controller 600, and the fifth sub-controller 700 cause mutual physical quantity interference, and based on prediction, transmit a correction value to each of the first sub-controller 300, the second sub-controller 400, the third sub-controller 500, the fourth sub-controller 600, and the fifth sub-controller 700. That is, the sub-system controller 1000 may transmit a correction amount due to the mutual physical quantity interference to each of the first to fifth sub-controllers 300, 400, 500, 600, and 700 and compensate for disturbance occurring between the first to fifth components. The correction amount may be in the form of a generalizable linear function, which may be determined through a system order, a DC gain, a frequency, and a damping ratio, and these parameters may be automatically optimized through iteration learning.

The semiconductor manufacturing facility 2000 may include the chamber 2050, the support 2100, the upper electrode 2500, the lower electrode 2550, the heater 2600, the stage 2300, the flow valve 2400, and the pressure valve 2200. In addition, the semiconductor manufacturing facility 2000 may further include at least one sensor for measuring a physical quantity to be controlled within the chamber 2050. For example, the semiconductor manufacturing facility 2000 may include a pressure sensor 2250 that detects chamber pressure, a temperature sensor that measures the temperature inside the chamber 2050, etc.

The chamber 2050 may include a space formed therein in which a process is performed. The support 2100 may be configured to support the substrate W. The support 2100 may be provided inside the chamber 2050 and may be provided on a lower side of the inside of the chamber 2050. The support 2100 may include the lower electrode 2550 embedded therein. In FIG. 1, the lower electrode 2550 is shown embedded inside the support 2100, but the inventive concept is not limited thereto. The lower electrode 2550 may be provided by being coupled to the outside of the support 2100, or may be provided inside the chamber 2050 by being spaced apart from the support 2100.

In FIG. 1 and the following description, an X-axis direction and a Y-axis direction may be directions parallel to an upper or lower surface of the substrate W, and may be perpendicular to each other. A Z-axis direction may be a direction perpendicular to the upper or lower surface of the substrate W. In other words, the Z-axis direction may be perpendicular to an X-Y plane.

In addition, in FIG. 1 and the following description, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The upper electrode 2500 may be provided on an outer upper portion of the chamber 2050. The upper electrode 2500 may be disposed to face the lower electrode 2550. The upper electrode 2500 may include a high frequency antenna. For example, the antenna may have a planar coil shape. The upper electrode 2500 may include an inner coil and an outer coil. The inner coil and the outer coil may each have a spiral shape or a concentric circle shape. The inner coil and the outer coil may generate an inductively coupled plasma in a plasma space of the chamber 2050. The upper electrode 2500 may receive plasma power having a sinusoidal waveform from a sinusoidal power supply device. That is, the sinusoidal power supply device may apply the plasma power to the upper electrode 2500 to form plasma inside the chamber 2050. The sinusoidal power supply device may include a source RF power source and a source RF matcher as plasma source elements. The source RF power source may generate an RF signal (or high frequency signal). The source RF matcher may control plasma to be generated using coils by matching an impedance of the RF signal generated from the source RF power source. The sinusoidal power supply device and the plasma power supply may also be referred to as a plasma power supply and plasma source power, respectively. The lower electrode 2550 may receive bias power (e.g., bias voltage) having a variable frequency and a non-sinusoidal waveform from a variable frequency non-sinusoidal power supply device. The variable frequency non-sinusoidal power supply device and the bias power may also be referred to as a bias power supply and bias source power, respectively.

The stage 2300 may be configured to drive the support 2100. For example, the stage 2300 may move the support 2100 in the vertical direction (Z) or the horizontal direction(s). Additionally, the stage 2300 may rotate the support 2100 around the Z-axis. In some embodiments, the stage 2300 may bring the support 2100 into the chamber 2050 or out of the chamber 2050.

The flow valve 2400 may be provided on an upper side of the chamber 2050. The flow valve 2400 may be configured to control the flow rate of fluid flowing into the chamber 2050. According to some embodiments, the flow valve 2400 may be connected to a gas supply. The gas supply may supply various gases into the chamber 2050. The flow valve 2400 may control a supply flow rate of fluid flowing into the chamber 2050 through the gas supply. In FIG. 1, the flow valve 2400 is shown as being formed on the upper side of the chamber 2050, but is not limited thereto. For example, the flow valve 2400 may be formed on a side portion or a lower side of the chamber 2050. Additionally, the number of flow valves 2400 may be two or more, and in this case, the flow valves 2400 may independently or jointly control supply flow rates of gases supplied into the chamber 2050.

The pressure valve 2200 may be configured to adjust the pressure inside the chamber 2050. According to some embodiments, the pressure valve 2200 may be formed on the lower side inside the chamber 2050, but is not limited thereto. The heater 2600 may be configured to adjust the temperature inside the chamber 2050 by applying heat into the chamber 2050, and, for example, may be coupled to a side wall of the chamber 2050.

The semiconductor manufacturing facility 2000 of the semiconductor manufacturing apparatus according to the embodiment may apply the physical quantity controller 150 having the feedforward control function shown in FIG. 2 to at least any one of the main system controller 100 and the sub-system controller 1000, thereby achieving the homeostasis of the semiconductor manufacturing process with fast physical quantity response performance.

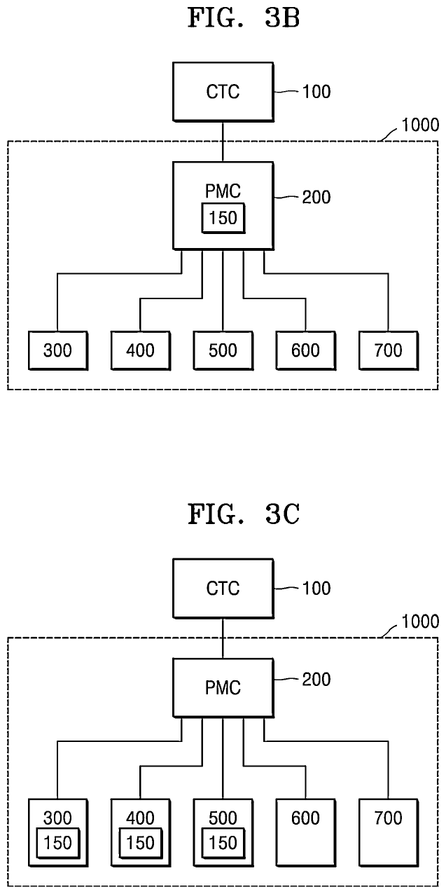

The physical quantity controller 150 may be applied to, for example, the main system controller 100, as shown in FIG. 3A. In this case, the main system controller 100 may generate a feedforward control signal and transmit a physical quantity control signal including the feedforward control signal as well as the process recipe to the sub-system controller 1000. The PMC 200 of the sub-system controller 1000 may transmit the physical quantity control signal including the input feedforward control signal to the corresponding sub-controller. The current response characteristics of the semiconductor manufacturing facility 2000, where the physical quantity is controlled by applying the feedforward control signal, may be transmitted to the main system controller 100, thereby reflecting the current system response in the feedforward control.

The physical quantity controller 150 may be applied to, for example, the sub-system controller 1000. In this case, the physical quantity controller 150 may be applied to the at least any one of PMC 200, the first to fifth sub-controllers 300, 400, 500, 600, and 700. For example, as shown in FIG. 3B, the physical quantity controller 150 may be applied to the PMC 200. In this case, the PMC 200 may generate the feedforward control signal and may transmit not only the process recipe transmitted from the main system controller 100 but also the physical quantity control signal including the feedforward control signal to the corresponding sub-controller. The current response characteristics of the semiconductor manufacturing facility 2000, where the physical quantity is controlled by applying the feedforward control signal, may be transmitted to the PMC 200, thereby reflecting the current system response in the feedforward control. For example, as shown in FIG. 3C, the physical quantity controller 150 may be applied to at least one of the first to fifth sub-controllers 300, 400, 500, 600, and 700 of the sub-system controller 1000. FIG. 3C shows an example in which the physical quantity controller 150 is applied to each of the first sub-controller 300, the second sub-controller 400, and the third sub-controller 500, but is not limited thereto. As described above, when the physical quantity controller 150 is applied to at least one sub-controller, the corresponding sub-controller may generate a feedforward control signal and control the corresponding physical quantity of the semiconductor manufacturing facility 2000 according to the process recipe transmitted from the main system controller 100 through the PMC 200 and according to the physical quantity control signal including the feedforward control signal. The current response characteristics of the semiconductor manufacturing facility 2000, where the physical quantity is controlled by applying the feedforward control signal, may be transmitted to the corresponding sub-controller, thereby reflecting the current system response in the feedforward control.

As described above, the physical quantity controller 150 including the feedforward control function according to some embodiments may be applied to the main system controller 100 and/or at least any one of the PMC 200, the first to fifth sub-controllers 300, 400, 500, 600, and 700 of the sub-system controller 1000 and may be configured to reflect the current system response in the feedforward control.

In the semiconductor manufacturing system 10 described with reference to FIG. 1, each physical quantity control system may be implemented by combining a configuration of a corresponding physical quantity controller of the main system controller 100 or the sub-system controller 1000, and a corresponding physical quantity control component of the semiconductor manufacturing facility 2000, etc. In addition, the configuration of the corresponding physical quantity controller may include the physical quantity controller 150 having the feedforward control function, as shown in FIG. 2. For example, a chamber pressure control system of a semiconductor etching process facility may include a combination of a configuration of a pressure controller of the main system controller 100 and the sub-system controller 1000 and the pressure valve 2200 and the pressure sensor 2250 that respectively adjust and sense the pressure of a process chamber 2050 of the semiconductor manufacturing facility 2000, and the configuration of the pressure controller may include the physical quantity controller 150 having the feedforward control function, as shown in FIG. 2.

That is, the physical quantity control system according to some embodiments may include the physical quantity controller 150 having the feedforward control function, as shown in FIG. 2. For example, when the physical quantity to be controlled is pressure, the physical quantity controller 150 of FIG. 2 may correspond to the pressure controller, and the physical quantity controller 150 may be configured to operate by receiving a pressure signal, and reflect a pressure sensing value of the process chamber 2050 in the feedforward control.

Referring to FIG. 2, the physical quantity controller 150 according to some embodiments may include a feedforward controller 170, a feedback controller 180, and a switching unit or switch 190 for switching between feedforward control and feedback control. The physical quantity controller 150 may be configured to reflect the current physical quantity control system response in the feedforward control. That is, a sensor measurement value PV for the physical quantity to be controlled of the process chamber 2050 may be fed back through the feedforward controller 170 as well as the feedback controller 180 so that the current system response may be reflected in the feedforward control. The physical quantity controller 150 according to some embodiments may further include a memory 160. The memory 160 may store a set value of a first stage feedforward FF1, a set value of a second stage feedforward FF2, a set value of a first switching point, a set value of a second switching point, a set value of a previous stage feedforward, a set value of a previous stage switching point, etc. In addition, the memory 160 may store a control algorithm of the physical quantity controller 150 according to some embodiments and software in which the control algorithm is implemented, etc.

During a feedforward control operation, the feedforward controller 170 may divide a feedforward output into two stages to control the physical quantity control system. The feedforward controller 170 may generate an output of a first stage feedforward FF1 to accelerate the physical quantity control system to a physical limit performance, and generate an output of the second stage feedforward FF2 to minimize overshoot by reducing acceleration of the physical quantity control system at the first switching point, and at the same time, to ensure smooth controller switching by setting the initial output of the subsequent feedback controller 180. During the feedforward operation, the switching unit 190 may be connected to the feedforward controller 170.

At this time, because the sensor measurement value PV is fed back to the feedforward controller 170, a control application amount of the first stage feedforward FF1 and a control application amount of the second stage feedforward FF2 may be adjusted based on the response of the physical quantity control system. That is, the feedforward controller 170 may output a feedforward control signal that reflects the current response characteristics of the semiconductor manufacturing facility 2000.

When the sensor measurement value PV reaches a switching point of the second stage feedforward FF2 and feedback FB controls, i.e. the second switching point, and the switching unit 190 is connected to the feedback controller 180, the feedforward control may be switched to feedback control, and the feedback controller 180 initialized to an output value of the second stage feedforward FF2 may perform regulation so that the physical quantity to be controlled maintains a target value.

The feedback controller 180 may generate an output for feedback control of the physical quantity control system to maintain a process physical quantity of the semiconductor manufacturing facility 2000 at the target value. When the output value of the second stage feedforward FF2 reaches the second switching point, the physical quantity controller 150 may be switched from feedforward control to feedback control.

When the physical quantity controller 150 is switched from feedforward control to feedback control, the output of the feedback controller 180 may be initialized to the output value of the second stage feedforward FF2. That is, the feedback controller 180 may include, for example, a proportional integral derivative (PID) controller to calculate a controller output from an error between the sensor measurement value PV and a command value even while a feedforward output is applied. An integral term of the PID controller may be initialized at the time of switching so that the output calculated from the feedback controller 180 is equal to that of the second stage feedforward FF2, and the sensor measurement value PV may be applied to a set value SV, and then gradually changed to the original set value SV so that the error starts from 0, and the output of the feedback controller 180 may be initialized to the output value of the second stage feedforward FF2.

Here, when a large difference occurs between the feedforward output and a calculation result of the feedback controller 180 at a switching point of a second stage feedforward-feedback FF2-FB, that is, the second switching point, this may cause instability of the control response during switching. However, as in some embodiments, when the output of the feedback controller 180 is initialized to the output value of the second stage feedforward FF2 so that the output of the physical quantity controller 150 is the same before and after switching from feedforward control to feedback control, smooth controller switching may be achieved without bumping, thereby preventing the instability of the control response.

In addition, the physical quantity controller 150 according to some embodiments may include a switching unit 190 to switch between feedforward control and feedback control according to the sensor measurement value PV of the physical quantity of the process chamber 2050. For example, the switching unit 190 may be connected to the feedforward controller 170 during feedforward control, and, when the sensor measurement value PV reaches the second switching point between the control of the second stage feedforward FF2 and the feedback FB control, may be connected to the feedback controller 180. Alternatively, the switching unit 190 may be provided so that the sensor measurement value PV of the physical quantity control system is fed back. That is, the switching unit 190 may be driven to switch between feedforward control and feedback control by reflecting the current response characteristics of the semiconductor manufacturing facility 2000.

According to the physical quantity control system according to some embodiments, for example, when a control set point of the facility physical quantity is changed, the switching unit 190 may be connected to the feedforward controller 170, the feedforward controller 170 may apply the first stage feedforward FF1 to the physical quantity control system to accelerate the physical quantity control system to the physical limit performance, and, when the sensor measurement value PV reaches the first switching point of the first stage feedforward FF1 and the second stage feedforward FF2, apply the second stage feedforward FF2 to reduce acceleration. When the sensor measurement value PV reaches the second switching point of the second stage feedforward FF2 and feedback control, the switching unit 190 may be connected to the feedback controller 180, switch to feedback control, and perform regulation at the target value.

For example, the chamber pressure control system of the semiconductor etching process facility is considered a representative example of a system that is difficult to model because types of gas used are diverse depending on the process, and a flow rate, pressure, and source and bias RF power vary significantly at each process stage.

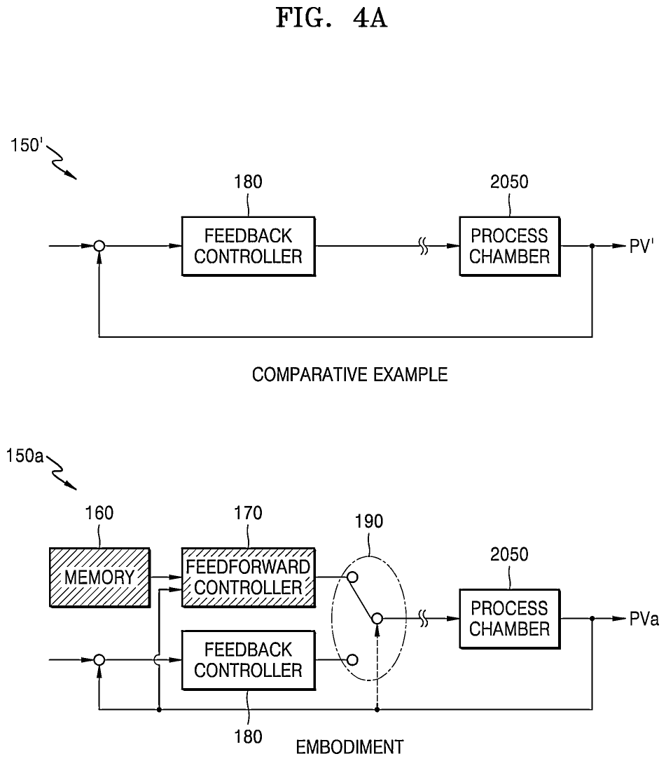

When the physical quantity controller 150 according to some embodiments is applied to the chamber pressure control system of the semiconductor etching process facility, the feedforward controller 170 and the feedback controller 180 are used at the same time, thereby securing fast control response performance and robust pressure control performance against disturbance by two stages of feedforward control and subsequent feedback control. FIG. 4A schematically shows block diagrams of an embodiment and a comparative example of a chamber pressure control system of a semiconductor etching process facility, and FIG. 4B shows comparison of the response performance of the embodiment and the comparative example of FIG. 4A.

As shown in FIG. 4A, in the chamber pressure control system of the comparative example, a pressure controller 150′ may include only the feedback controller 180, and a pressure sensor measurement value PV′ may be fed back to the feedback controller 180. On the other hand, in the chamber pressure control system of the embodiment, as described above with reference to FIG. 2, the pressure controller 150a may include the feedforward controller 170, the feedback controller 180, and the switching unit 190 for switching between feedforward control and feedback control and be configured to control chamber pressure through second stage feedforward control and subsequent feedback control and reflect system response characteristics, that is, a pressure sensor measurement value PVa, in the feedforward control.

As shown in FIG. 4B, in the chamber pressure control system of the comparative example, a valve position may be gradually adjusted according to a feedback control signal, and the pressure may be also adjusted gradually. On the other hand, the chamber pressure control system of the embodiment may be accelerated to the physical limit performance by an output of the first stage feedforward FF1, and then the acceleration may be reduced by an output of the second stage feedforward FF2 at a first switching point, and thus, a valve position may be rapidly adjusted at the first switching point, and pressure adjustment may be achieved with a fast response speed. In addition, during switching to feedback control at a second switching point, the feedback controller 180 may be initialized to an output value of the second stage feedforward FF2, and thus, controller switching may be smoothly achieved and overshoot may be minimized. In FIG. 4B, (a), (b), and (c) periods may respectively indicate a control period of the first stage feedforward FF1, a control period of the second stage feedforward FF2, and a feedback FB adjustment period, in the chamber pressure control system according to the embodiment.

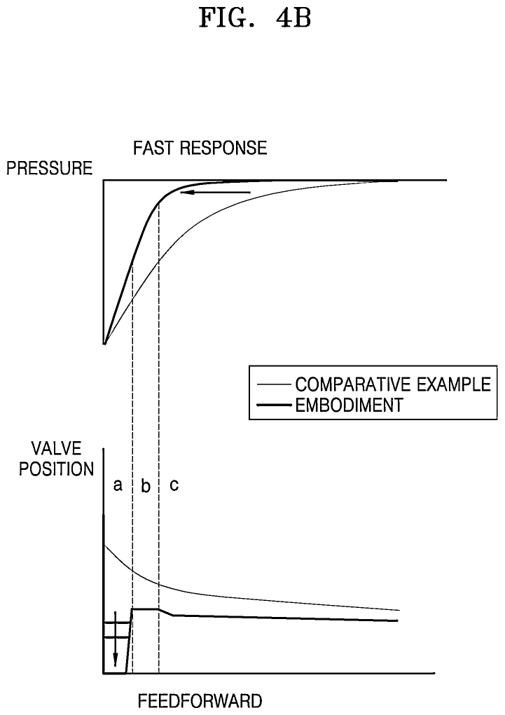

As may be seen in FIG. 5, which shows the response characteristics of the chamber pressure control system of the semiconductor etching process facility according to the embodiment, in order to control a physical quantity of the semiconductor manufacturing facility 2000 of the semiconductor manufacturing device by the physical quantity control system according to the embodiment, by iterating the adjustment, an output value of the first stage feedforward FF1, an output value of the second stage feedforward FF2, and set values of the first switching point and the second switching point may be automatically optimized from a control performance indicator determined by the measurement value PV of a sensor. At this time, the control performance indicator is a main control performance indicator and may be at least one of a response speed, an overshoot percentage, a stabilization time, a rise time, an undershoot percentage, and a steady-state error.

The first switching point and the second switching point may be determined by determining the output value of the first stage feedforward FF1, the output value of the second stage feedforward FF2, and the output value of the feedback FB control that match the physical quantity characteristics, and iteratively tuning the control of the first stage feedforward FF1 for fast response in a transient period and the control of the second stage feedforward FF2 for reducing overshoot. At this time, when the first switching point is set to a % of a change amount of a physical quantity to be controlled, and the second switching point is set to b % of the change amount of the physical quantity to be controlled, there is a relationship of 0<a<b<100.

The first switching point and the second switching point may be determined according to the response performance of an individual physical quantity, advanced for a physical quantity with a fast response, and delayed for a physical quantity with a slow response. In other words, the first switching point and the second switching point may be user-set constants, which may advance a switching point when the first switching point and the second switching point have fast response characteristics such as flow control, and may delay the switching point when the first switching point and the second switching point have slow response characteristics such as temperature control. In addition, in the case of pressure control having response characteristics between flow rate and temperature, when the first switching point is set to 50% to 60% of the set value SV, and the second switching point is set to 80% to 90% of the set value SV, an appropriate response performance may be observed.

FIG. 5 is a graph showing response characteristics of a chamber pressure control system of a semiconductor etching process facility according to an embodiment. FIG. 5 shows an example in which a first switching point is set to 50% of the set value SV and a second switch point is set to 80% of the set value SV. In FIG. 5, the number of iterations increases as ‘Iter1′<′Iter2′<′Iter3′<′Iter4′<′Iter5’.

As shown in FIG. 5, feedforward control is performed in two stages. To bring out the physical limit performance of the chamber pressure control system, the first stage feedforward FF1 may be applied, and, when a measurement value of a physical quantity to be controlled, i.e., pressure, reaches a FF1-FF2 first switching point (i.e., 50% of a command change amount), switched to the second stage feedforward FF2 to prevent excessive overshoot and prepare for switching to feedback FB control. When the measurement value of pressure reaches a FF2-FB second switching point (i.e., 80% of the command change amount), the second stage feedforward FF2 may be switched to feedback FB control to remove a steady-state error and perform regulation to a target value. Even while an output of the feedback FB is not applied, the feedback controller 180 may calculate a controller output from an error between the sensor measurement value PV and a command value. Therefore, when a large difference occurs between the output of the second stage feedforward FF2 and a feedback FB operation result at the FF2-FB second switching point, this may cause instability of the control response during switching. According to the chamber pressure control system according to the embodiment, as shown in FIG. 5, a valve position in a steady-state of the feedback FB period may be applied to the second stage feedforward FF2 to make sure there is no significant difference between the output of the second stage feedforward FF2 and the feedback FB. For example, the output of the feedback controller 180 may be initialized to the value of the second stage feedforward FF2, thereby flexibly responding to a facility change.

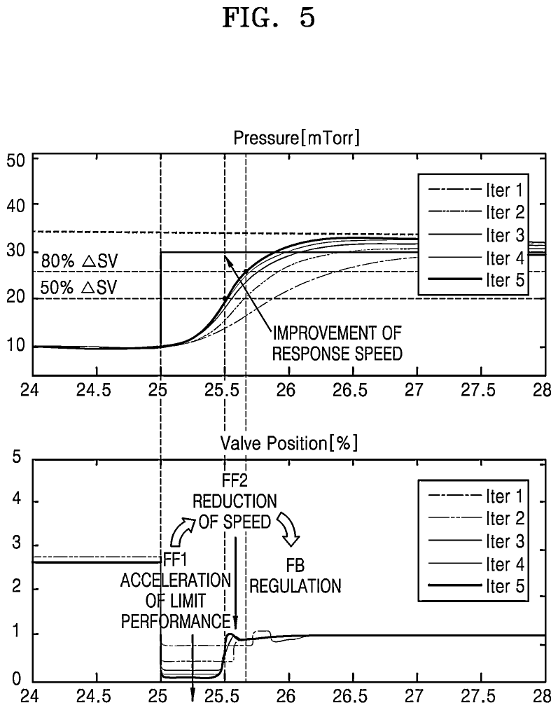

FIG. 6 is a graph showing response characteristics at a switching point between the second stage feedforward FF2 control and feedback FB control. FIG. 6 shows an example of a pressure control system.

Referring to FIG. 6, when an output of the feedback FB is initialized to an output value of the second stage feedforward FF2 at the switching point between the second stage feedforward FF2 control and feedback FB control, that is, a second switching point, it may be seen that a valve position is stabilized to a control position and the pressure is fast stabilized. On the other hand, when switching to feedback FB control without initializing the output of the feedback FB, it may be seen that a valve operation amount jumps and it takes time for the valve position to stabilize to the control position, and it also takes time for the pressure to stabilize.

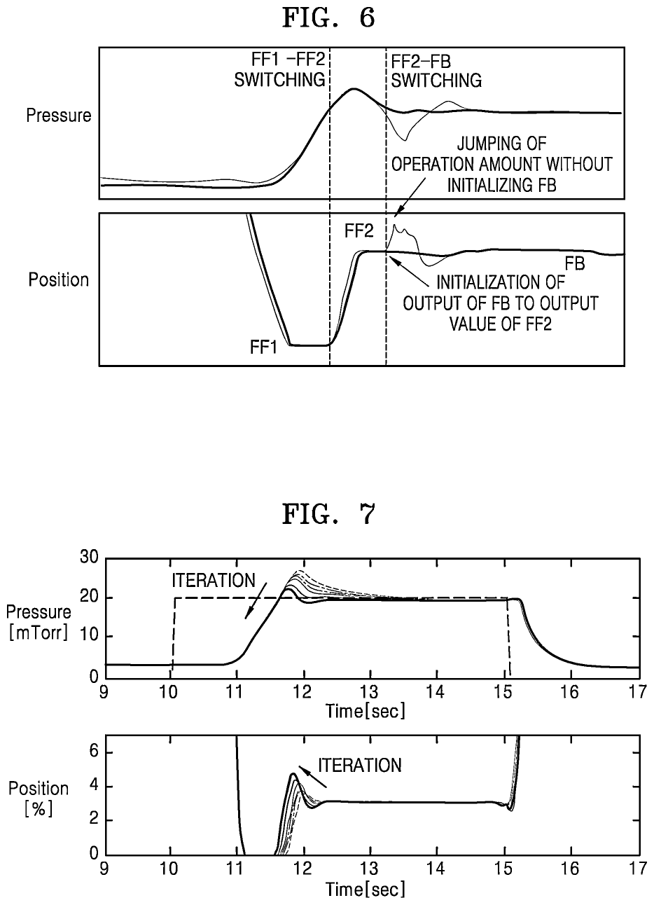

In addition, set values of first and second switch points, a set value of a feedback FB initial value at an FF2-FB second switch point, etc. may be optimized through iteration trials. From major control performance indicators (a response speed, an overshoot percentage, a stabilization time, a risc time, an undershoot percentage, a steady-state error, etc.) that may be determined in the sensor measurement value PV, an output value of the first stage feedforward FF1, an output value of the second stage feedforward FF2, and FF1-FF2-FB switching points may be iteratively adjusted, and thus, a set value for optimal response may be automatically determined. First, after determining FF1-FF2-FB that matches the characteristics of individual physical quantities, the first stage feedforward FF1 for speeding up rise-up and the second stage feedforward FF2 for reducing overshoot may be iteratively tuned. As shown in FIG. 7, to accelerate the system to a physical limit, the first stage feedforward FF1 may remain at 0 (valve completely closed), and to reduce overshoot, a continuous rise (valve opened) of the second stage feedforward FF2 may be observed. Through an iterative adjustment of a feedforward application amount based on a system response, the optimal pressure control performance of the desired standard may be secured.

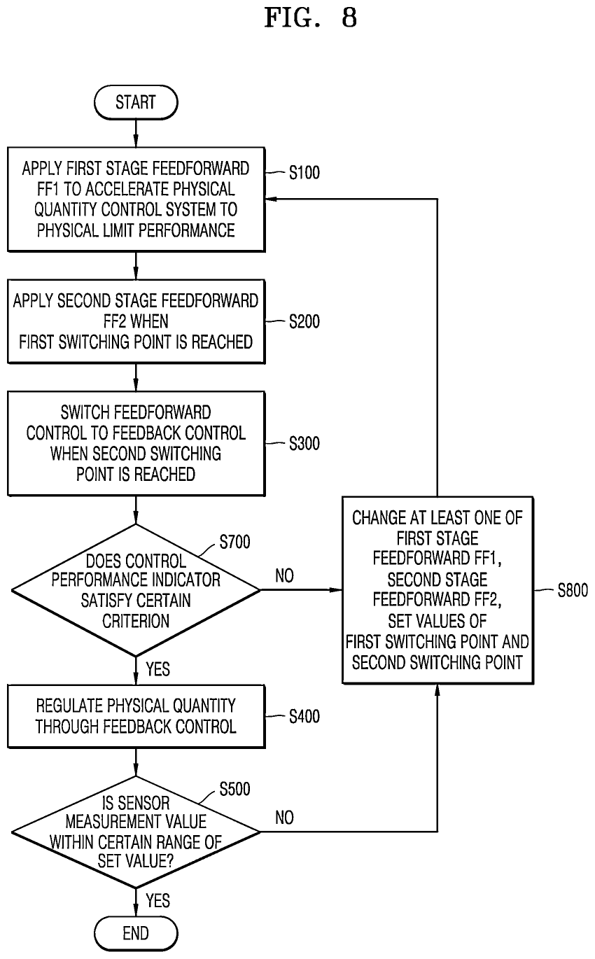

FIG. 8 is a flowchart schematically showing a method of controlling a physical quantity of a semiconductor manufacturing apparatus according to some embodiments.

Referring to FIG. 8, in order to control a process physical quantity of the semiconductor manufacturing apparatus, feedforward control may be performed (S100 and S200). Feedforward control may include performing control of the first stage feedforward FF1 to accelerate a physical quantity control system to the physical limit performance (S100) and performing control of the second stage feedforward FF2 when a first switching point is reached (S200). When an output value of the second stage feedforward FF2 reaches a second switching point, feedforward control may be switched to feedback control and physical quantity adjustment may be performed through feedback control (S300). Feedback control may be initialized with an output value of the second stage feedforward FF2 at the second switching point and performed so that a process physical quantity is maintained at a target value. As described above, after switching to feedback control, it may be determined whether a control performance indicator confirmed from the sensor measurement value PV satisfies a certain criterion (S700). When the control performance indicator does not satisfy the certain criterion, at least one of the first stage feedforward FF1, the second stage feedforward FF2, or set values of the first switching point, and the second switching point may be changed (S800) and the above process is repeated to automatically optimize. When the control performance indicator satisfies the certain criterion, physical quantity adjustment may be performed for a certain period of time through feedback control (S400).

During a physical quantity control process, the physical quantity may be measured by a sensor at regular time intervals to determine whether the sensor measurement value PV is within a certain range of the set value SV (S500). The sensor measurement value PV in operation S500 may be fed back to at least one operation of determining a control performance indicator (S700), controlling feedforward (S100 and/or S200), switching to feedback FB control, performing physical quantity adjustment through feedback control (S300 and S400), and changing the set value (S800). FIG. 8 shows that the sensor measurement value PV in operation S500 is fed back to operation (S800) of changing the set value, but the inventive concept is not limited thereto.

As described above, the sensor measurement value PV may be fed back to operation (S800) of changing the set value or operation (S100 and/or S200) of controlling feedforward, and a control application amount of the first stage feedforward FF1 and a control application amount of the second stage feedforward FF2 may be adjusted based on a response of the physical quantity control system. When the sensor measurement value PV is within a certain range of the set value SV, feedback control may be continuously performed to maintain the process physical quantity at the target value (S400).

In addition, when the sensor measurement value PV is outside the certain range from the set value SV or a control set point of the facility physical quantity is changed, the set value SV may be changed in operation S800, and a process of controlling the process physical quantity may start again from performing the control of the first stage feedforward FF1 (S100).

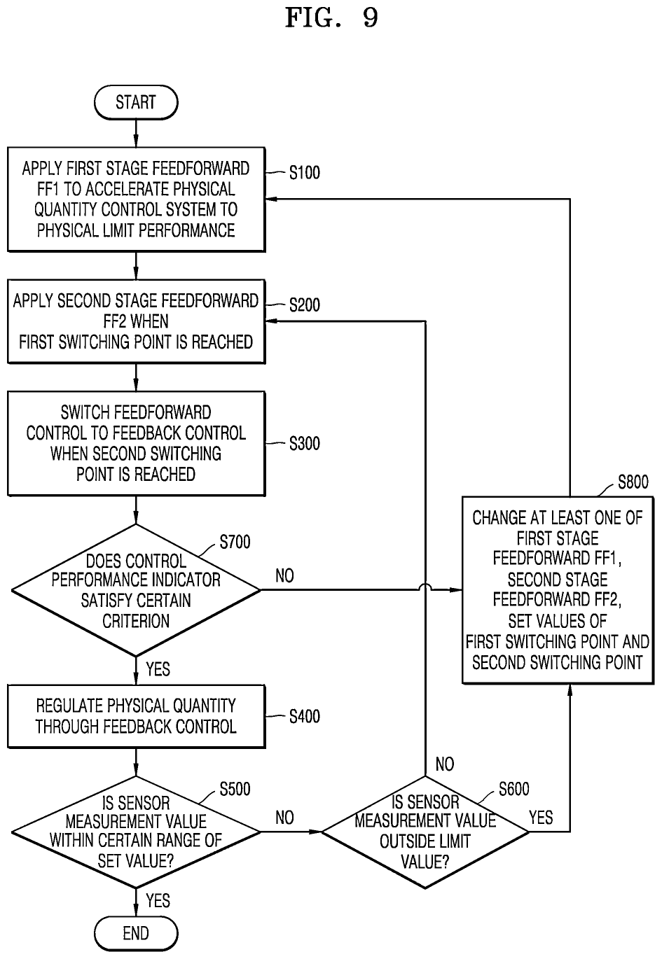

FIG. 9 is a flowchart schematically showing a method of controlling a physical quantity of a semiconductor manufacturing apparatus according to some other embodiments, and corresponds to a modified example of FIG. 8.

As illustrated in FIG. 9, according to a degree to which the sensor measurement value PV is outside the set value SV, a process of controlling a process physical quantity may selectively start again from performing control of the first stage feedforward FF1 (S100) or performing control of the second stage feedforward FF2 (S200). As shown in FIG. 9, in operation S500, when the sensor measurement value PV is outside the certain range of the set value SV, in order to implement fast response performance, it may be determined whether the sensor measurement PV corresponds to or greater than a limit value that requires starting from the control of the first stage feedforward FF1 (S600). When the sensor measurement value PV is outside a limit value range, the process of controlling the process physical quantity may start again from the control of the first stage feedforward FF1 by changing the set value SV in operation S800 and applying the changed set value SV. When a degree to which the sensor measurement value PV is outside the limit value range is not significant, the process of controlling the process physical quantity may start again from the control of the second stage feedforward FF2 so as to reduce the feedforward control time. Here, the certain range of the set value SV may correspond to a range in which the physical quantity control is performed through feedback control, and the limit value may correspond to a range in which feedforward control is required for fast response performance outside the certain range of the set value SV.

When chamber pressure is controlled, in operation S100, in order to accelerate the system to the physical limit, an output value of the first stage feedforward FF1 may remain at 0 and be controlled so that a valve is completely closed, and in operation S200, an output value of the second stage feedforward FF2 may be controlled to a continuous rise so that the valve is opened. After a first switching point and a second switching point suitable for individual physical quantity characteristics are determined, control of the first stage feedforward FF1 for speeding up a rise and control of the second stage feedforward FF2 for reducing overshoot may be iteratively tuned. As shown in FIGS. 8 and 9, because the sensor measurement value PV is fed back to feedforward control and feedback control, the system response characteristics may be reflected in feedforward control, and thus, through an iterative adjustment of a feedforward application amount based on a system response, the optimal pressure control performance may be secured.

The physical quantity controlled by the physical quantity controller 150 and the method of controlling the physical quantity of the semiconductor manufacturing apparatus according to the embodiments described with reference to FIGS. 8 and 9 may include at least one of the pressure inside the semiconductor manufacturing apparatus, the flow rate of fluid flowing into the semiconductor manufacturing apparatus, RF power applied to the semiconductor manufacturing apparatus, and the process temperature of the semiconductor manufacturing apparatus. One physical quantity to be controlled or each of a plurality of physical quantities to be controlled may be controlled through feedforward control and the feedback control.

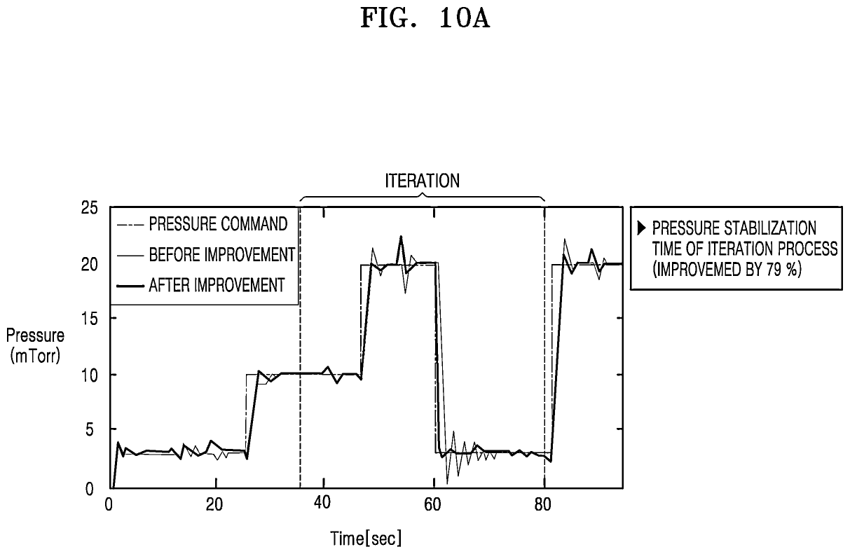

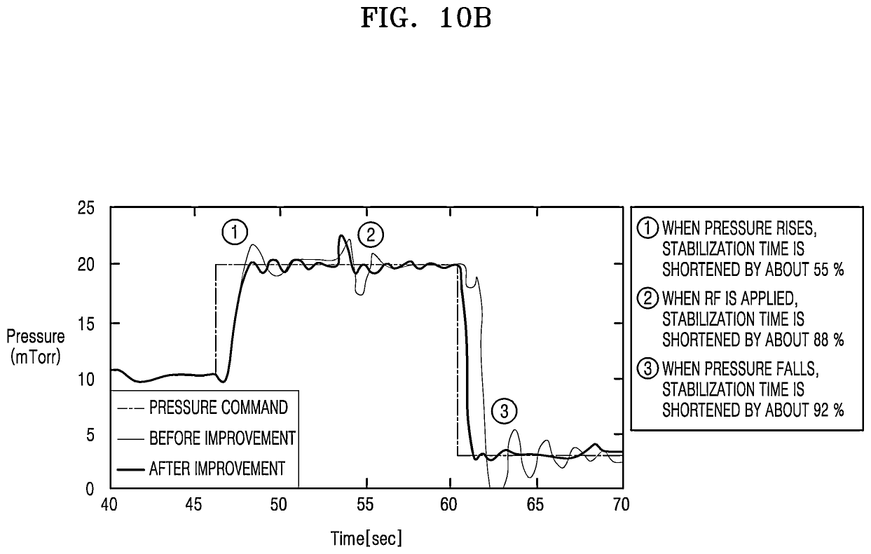

FIG. 10A is a graph showing an example of securing robust and fast pressure control performance by applying the physical quantity controller 150 according to the embodiment to a semiconductor etching process facility, compared to before improvement, and FIG. 10B is an enlarged graph showing an iteration period of FIG. 10A. FIGS. 10A and 10B show that when applying the physical quantity controller 150 according to the embodiment to a DRAM shallow trench isolation (STI) etch process facility, the total etching process time may be shortened by securing fast and stable response performance, and the homeostasis of a process may be improved by robustly controlling a physical quantity to be controlled without fluctuation.

As shown in FIGS. 10A and 10B, for example, it may be seen that the total process time in which the pressure is stabilized to a command+1 mTorr in an iteration process is shortened from 108 s to 22 s, that is, about 79%, without any change in a process result. It may be seen that when the pressure rises, a stabilization time is shortened by about 55% (1), when RF is applied, the stabilization time is shortened by about 88% (2), and when the pressure falls, the stabilization time is shortened by about 92% (3). Shortening the process time may lead to increased productivity. In addition, by comparing the response characteristics graph after improvement and before improvement shown in FIGS. 10A and 10B, it may be confirmed that the physical quantity controller 150 and the control method according to the embodiment may increase productivity by a fast response and also improve the homeostasis of a process by robustly controlling the physical quantity to be controlled without fluctuation.

In the above, it has been specifically described that the physical quantity controller 150 and the control method according to embodiments are applied to control the chamber pressure, but the inventive concept is not limited thereto. As described above, the physical quantity controller 150 and the control method according to embodiments may be applied to control not only the chamber pressure, but also the flow rate inside the chamber, RF power, process temperature, electromagnetic physical quantity, mechanical physical quantity, etc.

According to the physical quantity controller 150 and the control method according to some embodiments, feedforward control of two stages, including control of the first stage feedforward FF1 and control of the second stage feedforward FF2, and feedback control may be performed, and when switching to feedback control, the output of feedback FB control may be initialized to the output value of the second stage feedforward FF2, and the system response may be reflected in feedforward control. Therefore, even with respect to the physical quantity to be controlled that is incapable of sophisticated modeling, and thus has a large modeling error or a time variant change in a model parameter, such as pressure, flow rate, RF power, temperature, etc., it may be controlled with a fast response and robustly controlled against facility fluctuations or disturbances, thereby flexibly responding to the modeling error and improving the homeostasis or stability of a process. In addition, the fast response performance may be secured regardless of model matching.

While the inventive concept has been particularly shown and described with reference to embodiments thereof, it will be understood that various changes in form and details may be made therein without departing from the spirit and scope of the following claims.

What is claimed is:

1. A semiconductor manufacturing system comprising:
a main system controller;
a sub-system controller configured to receive a process recipe from the main system controller; and
a semiconductor manufacturing facility controlled by the sub-system controller and where a semiconductor process is performed based on the process recipe received from the main system controller,
wherein the sub-system controller comprises a process module controller (PMC) and a plurality of sub-controllers, and
wherein at least one of the main system controller, the PMC, and the plurality of sub-controllers of the sub-system controller comprises:
a feedforward controller configured to perform feedforward control comprising control of a first stage feedforward to accelerate a physical quantity control system to a physical limit performance and control of a second stage feedforward to reduce acceleration of the physical quantity control system at a first switching point;
a switching unit configured to switch the feedforward control to feedback control at a second switching point; and
a feedback controller configured to perform feedback control on the physical quantity control system.

2. The semiconductor manufacturing system of claim 1, wherein an output of the feedback control is initialized to an output value of the second stage feedforward after switching to the feedback control at the second switching point.

3. The semiconductor manufacturing system of claim 1, wherein a control application amount of the first stage feedforward and a control application amount of the second stage feedforward are adjusted based on a response of the physical quantity control system.

4. The semiconductor manufacturing system of claim 1, wherein an output value of the first stage feedforward, an output value of the second stage feedforward, and set values of the first switching point and the second switching point are automatically optimized from a control performance indicator output from a measurement value of a sensor by iterating adjustment.

5. The semiconductor manufacturing system of claim 4, wherein the control performance indicator includes at least one of a response speed, an overshoot percentage, a stabilization time, a rise time, an undershoot percentage, and a steady-state error.

6. The semiconductor manufacturing system of claim 1, wherein the first switching point and the second switching point are determined according to a response performance of the physical quantity, are advanced with respect to a physical quantity having a fast response, and are delayed with respect to a physical quantity having a slow response.

7. The semiconductor manufacturing system of claim 6, wherein
the first switching point and the second switching point are determined by determining an output value of the first stage feedforward, an output value of the second stage feedforward, and an output value of the feedback control that match characteristics of the physical quantity, and
iteratively tuning control of the first stage feedforward for fast response in a transient period and control of the second stage feedforward for reducing overshoot.

8. The semiconductor manufacturing system of claim 6, wherein the first switching point is set to a % of a change amount of a physical quantity to be controlled, and the second switching point is set to b % of the change amount of the physical quantity to be controlled, where there is a relationship of 0<a<b<100.

9. The semiconductor manufacturing system of claim 1, wherein a physical quantity controlled by the physical quantity control system includes at least one of
pressure inside the semiconductor manufacturing apparatus,
a flow rate of fluid flowing into the semiconductor manufacturing apparatus,
radio frequency (RF) power applied to the semiconductor manufacturing apparatus,
a process temperature of the semiconductor manufacturing apparatus,
an electromagnetic physical quantity applied to the semiconductor manufacturing apparatus, and
a mechanical physical quantity applied to the semiconductor manufacturing apparatus, and
one physical quantity to be controlled or each of a plurality of physical quantities to be controlled is controlled through the feedforward control and the feedback control.

10. A semiconductor manufacturing system comprising:
a semiconductor manufacturing facility comprising a process chamber, at least one electrode configured to apply power or an electromagnetic physical quantity to the process chamber, a heater configured to apply heat to an inside of the process chamber, a flow valve configured to control a flow rate of fluid flowing into the process chamber, a pressure valve configured to control pressure of the inside of the process chamber, a stage configured to drive a support, and at least one sensor configured to measure a physical quantity to be controlled in the process chamber; and
a system controller comprising a process module controller (PMC) and a plurality of sub-controllers and configured to control the semiconductor manufacturing facility where a semiconductor manufacturing process is performed,
wherein at least one of the PMC and the plurality of sub-controllers comprises:
a feedforward controller configured to feedforward control a physical quantity control system to output a first stage feedforward to accelerate the physical quantity control system to a physical limit performance and to output a second stage feedforward to reduce acceleration of the physical quantity control system at a first switching point;
a feedback controller configured to feedback control the physical quantity control system; and
a switching unit configured to switch from feedforward control to feedback control at a second switching point.

11. The semiconductor manufacturing system of claim 10, wherein an output of the feedback controller is initialized to an output value of the second stage feedforward after switching to the feedback control at the second switching point.

12. The semiconductor manufacturing system of claim 10, wherein a control application amount of the first stage feedforward and a control application amount of the second stage feedforward are adjusted based on a response of the physical quantity control system.

13. The semiconductor manufacturing system of claim 10, wherein, by iterating adjustment, an output value of the first stage feedforward, an output value of the second stage feedforward, and set values of the first switching point and the second switching point are automatically optimized from a control performance indicator output from a measurement value of the at least one sensor.

14. The semiconductor manufacturing system of claim 13, wherein the control performance indicator includes at least one of a response speed, an overshoot percentage, a stabilization time, a rise time, an undershoot percentage, and a steady-state error.

15. The semiconductor manufacturing system of claim 10, wherein the first switching point and the second switching point are determined according to a response performance of the physical quantity, are advanced with respect to a physical quantity having a fast response, and are delayed with respect to a physical quantity having a slow response.

16. The semiconductor manufacturing system of claim 15, wherein the first switching point and the second switching point are determined by determining an output value of the first stage feedforward, an output value of the second stage feedforward, and an output value of the feedback control that match characteristics of the physical quantity, and iteratively tuning control of the first stage feedforward for fast response in a transient period and control of the second stage feedforward for reducing overshoot.

17. The semiconductor manufacturing system of claim 15, wherein the first switching point is set to a % of a change amount of a physical quantity to be controlled, and the second switching point is set to b % of the change amount of the physical quantity to be controlled, where there is a relationship of 0<a<b<100.

18. The semiconductor manufacturing system of claim 10, wherein
the physical quantity includes at least one of pressure inside the process chamber, a flow rate, radio frequency (RF) power, a process temperature, an electromagnetic physical quantity, and a mechanical physical quantity, and
one physical quantity to be controlled or each of a plurality of physical quantities to be controlled is controlled through the feedforward control and the feedback control.

19. A semiconductor manufacturing system comprising:
a main system controller;
a sub-system controller configured to receive a process recipe from the main system controller; and
a semiconductor manufacturing facility controlled by the sub-system controller and where a semiconductor process is performed based on the process recipe received from the main system controller,
wherein the semiconductor manufacturing facility comprises
a process chamber, at least one electrode configured to apply radio frequency (RF) power or an electromagnetic physical quantity to generate plasma within the process chamber, a heater configured to apply heat to an inside of the process chamber, a flow valve configured to control a flow rate of fluid flowing into the process chamber, a pressure valve configured to control pressure of the inside of the process chamber, a stage configured to drive a support, and at least one sensor configured to measure a physical quantity to be controlled in the process chamber,
the sub-system controller comprises a process module controller (PMC) and a plurality of sub-controllers,
at least one of the main system controller, the PMC, and the plurality of sub-controllers of the sub-system controller comprises:
a feedforward controller configured to feedforward control a physical quantity control system to output a first stage feedforward to accelerate the physical quantity control system to a physical limit performance and output a second stage feedforward to reduce acceleration of the physical quantity control system at a first switching point;
a feedback controller configured to feedback control the physical quantity control system; and
a switching unit configured to switch from feedforward control to feedback control at a second switching point.

20. The semiconductor manufacturing system of claim 19, wherein an output of the feedback controller is initialized to an output value of the second stage feedforward after switching to the feedback control at the second switching point.
